(19) United States
(12) Patent Application Publication
(10) Pub. No.: US 2023/0408544 A1
(43) Pub. Date: Dec. 21, 2023

(54) METHOD, SYSTEM, COMPUTING DEVICE AND STORAGE MEDIUM FOR OPTICAL MEASUREMENT

(71) Applicant: Shanghai Ideaoptics Corp., Ltd., Shanghai (CN)

(72) Inventors: Tongyu Li, Shanghai (CN); Ang Chen, Shanghai (CN); Lei Shi, Shanghai (CN); Guopeng Lu, Shanghai (CN); Minjia Zheng, Shanghai (CN); Lingjie Fan, Shanghai (CN); Haiwei Yin, Shanghai (CN)

(21) Appl. No.: 18/037,569

(22) PCT Filed: Feb. 1, 2021
(86) PCT No.: PCT/CN2021/074611

§ 371 Date: May 18, 2023

(30) Foreign Application Priority Data
Nov. 20, 2020 (CN) 202011312192.1

(51) Int. Cl. G01Q 60/38; G01M 11/02

(52) U.S. Cl. CPC G01Q 60/38; G01M 11/0214

(57) ABSTRACT

A method comprises: generating input data for inputting to a neural network model based on coordinate data of dispersion curve data and preset values of geometric parameters with respect to a reference model; generating simulated dispersion curve data associated with the preset values of the geometric parameters based on the neural network model trained via a plurality of samples; obtaining measured dispersion curve data in relation to an object calculating a distance of the measured dispersion curve data from the simulated dispersion curve data to determine whether the distance meets a predetermined condition; and in response to determining the distance does not meet the predetermined condition, determining a gradient for updating the preset values of the geometric parameters with respect to the reference model based on the distance, to regenerate simulated dispersion curve data via the neural network model based on the updated preset values to recalculate the distance.

### FIELD

Embodiments of the present disclosure generally relate to the field of measurement, and more specifically, to methods, systems, computing devices, and non-transitory machine-readable storage medium for optical measurement.

### BACKGROUND

With the development of fabricating technology of precision components such as grating, requirements for measurement accuracy and efficiency of parameters of the measuring object, such as grating, are increasing. Conventional optical measurement schemes for a measuring object (e.g., the grating) comprise, for example: first, establishing a geometric model, and analog computing and storing optical responses of the geometric model in a database; then, experimentally obtaining optical responses of the measured optical responses by using Meuller matrix and so on; thereafter, searching simulated optical responses closest to the measured optical responses in the database by using search algorithms, so as to compute geometric parameters of the measuring objects.

In the above-mentioned conventional optical measurement schemes for a measuring object (such as the grating), with simulation algorithms, analog computations are necessary for all parameters in the spatial range of the geometric model so as to obtain the corresponding optical responses. Thus, it requires a large amount of computations, and takes a long time. Further, during the measurement, it also takes a long time to measure the optical responses with the Meuller matrix. In addition, the size of the database increases exponentially with the increase of the number of parameters used in the geometric model established by the samples to be measured and the solution range of each parameter. Therefore, in terms of the geometric model whose parameters vary in a range of hundreds of nanometers, solving the geometric parameters of the measuring object will be restricted by the size of the database and the search time.

In summary, conventional optical measurement schemes for the measuring object have disadvantages such as large amount of computations, time-consuming, and easy to be restricted by the size of the database of the samples to be measured.

### SUMMARY

The present disclosure provides methods, systems, computing devices, and non-transitory machine-readable storage medium for optical measurement, enabling accurate and rapid optical measurement on the measuring object.

In a first aspect of the present disclosure, it provides a method for optical measurement. The method comprises: generating input data for inputting to a neural network model based on coordinate data of dispersion curve data and preset values of geometric parameters with respect to a reference model; extracting features of the input data based on the neural network model trained via a plurality of samples, so as to generate simulated dispersion curve data associated with the preset values of the geometric parameters, the simulated dispersion curve data indicating a plurality of optical responses corresponding to a plurality of coordinate data of the dispersion curve data; obtaining measured dispersion curve data in relation to a measuring object; calculating a distance of the measured dispersion curve data from the simulated dispersion curve data, so as to determine whether the distance meets a predetermined condition; and in response to determining the distance does not meet the predetermined condition, determining a gradient for updating the preset values of the geometric parameters with respect to the reference model based on the distance, so as to regenerate simulated dispersion curve data via the neural network model based on the updated preset values to recalculate the distance.

In a second aspect of the present disclosure, it also provides a computing device. The device comprises: at least one processing unit; at least one memory coupled to the at least one processing unit and configured to store instructions for execution by the at least one processing unit. The instructions, when executed by the at least one processing unit, enable the device to perform the method of the first aspect of the present disclosure.

In a third aspect of the present disclosure, it further provides a computer-readable storage medium. The computer readable storage medium has stored computer program thereon, which when executed by a machine performs the method of the first aspect of the present disclosure.

In a fourth aspect of the present disclosure, it further provides a measuring system. The measuring system comprises: an angle-resolved spectrometry configured to measure a measuring object based on incident light so as to generate an optical energy band with respect to the measuring object; and a computing device configured to be operable to perform the method of the first aspect of the present disclosure.

In some embodiments, the method for optical measurement further comprises: in response to determining the distance meets the predetermined condition, determining the geometric parameters of the measuring object based on preset values corresponding to the input data for generating the current simulated dispersion curve data. The coordinate data comprises: angle and wavelength, or frequency and wave vector.

In some embodiments, determining the gradient for updating the preset values of the geometric parameters with respect to the reference model based on the distance, so as to regenerate the simulated dispersion curve data to recalculate the distance comprises: determining the gradient for updating the preset values of the geometric parameters with respect to the reference model based on the distance; updating the preset values of the geometric parameters with respect to the reference model based on the gradient, so as to generate updated input data based on the updated preset values; and inputting the updated input data to the neural network model, and regenerating simulated dispersion curve data associated with the updated preset value.

In some embodiments, generating the simulated dispersion curve data associated with the preset values of the geometric parameters comprises: based on predetermined geometric parameters with respect to the reference model and coordinate data of the dispersion curve data varying within a predetermined range, generating reflectivity data corresponding to each coordinate data varying within the predetermined range via the neural network model; and generating the simulated dispersion curve data based on the each coordinate data varying within the predetermined range and reflectivity data corresponding to the each coordinate data.

In some embodiments, the simulated dispersion curve data comprises a thin film interference portion indicating a smooth change and a grating energy band portion indicating an abrupt-sharp change.

In some embodiments, a plurality of samples used to train the neural network model are generated based on a rigorous coupled wave analysis algorithm or a finite difference time domain algorithm.

In some embodiments, a plurality of samples used to train the neural network model are generated based on a rigorous coupled wave analysis algorithm or a finite difference time domain algorithm. Generating the reflectivity data corresponding to the each coordinate data varying within the predetermined range via the neural network model comprises: generating a plurality of sub-input data based on the predetermined geometric parameters with respect to the reference model and the coordinate data of the dispersion curve data varying within the predetermined range; inputting the plurality of sub-input data to a plurality of neural network models configured on a plurality of GPUs, respectively, the plurality of sub-input data comprising same predetermined geometric parameters and different coordinate data; and extracting features of the corresponding sub-input data respectively via the plurality of neural network models, so as to respectively generate a plurality of reflectivity data corresponding to coordinate data comprised in the plurality of sub-input data.

In some embodiments, generating the simulated dispersion curve data associated with the preset values of the geometric parameters comprises: randomly determining a plurality of initialized preset values of the geometric parameters with respect to the reference model; generating a plurality of candidate simulated dispersion curve data associated with the plurality of initialized preset values respectively via the neural network model based on the plurality of initialized preset values; comparing a plurality of first distances between the plurality of candidate simulated dispersion curve data and the measured dispersion curve data, so as to respectively update gradients of the plurality of initialized preset values based on the plurality of first distances, for determining candidate simulated dispersion curve data enabling the corresponding first distances reach a minimum value; comparing a plurality of second distances between the candidate simulated dispersion curve data enabling the corresponding first distances reach the minimum value and the measured dispersion curve data, respectively, so as to take the candidate simulated dispersion curve data corresponding to the minimum second distance as target dispersion curve data; and computing the geometric parameters of the measuring object based on the target simulated dispersion curve data.

In some embodiments, the predetermined condition comprises one of the followings: the Euclidean distance between the measured dispersion curve data and the simulated dispersion curve data is the smallest; and the Euclidean distance between the measured dispersion curve data and the simulated dispersion curve data is less than a predetermined threshold.

In some embodiments, the measured dispersion curve data is wherein the measured dispersion curve data is a dispersion curve graph of the measuring object in momentum space under irradiation of incident light obtained based on measured dispersion curve data of momentum space of the background in which the measuring object is located, dispersion curve data of momentum space of a light source, and measured initial dispersion curve data of momentum space of the measuring object.

It should also be understood that, the content described in Summary is not intended to limit the key features or essential features of the embodiments of the present disclosure, nor is it intended to be used to limit the scope of the present disclosure. Other features of the embodiments of the present disclosure will become readily apparent from the following description.

### BRIEF DESCRIPTION OF THE DRAWINGS

Through the following detailed description with reference to the accompanying drawings, the above and other features, advantages and aspects of embodiments of the present disclosure will become more apparent. In the drawings, the same or similar reference numbers usually refer to the same or similar components, wherein:

FIG. 1 illustrates a schematic diagram of an example system that can be used for a method of optical measurement according to an embodiment of the present disclosure;

FIG. 2 illustrates a flowchart of a method for optical measurement according to an embodiment of the present disclosure;

FIG. 3 illustrates a schematic diagram of a reference model according to an embodiment of the present disclosure;

FIG. 4 illustrates a flowchart of a method for generating reflectivity data corresponding to the coordinate data varying within a predetermined range according to an embodiment of the present disclosure;

FIG. 5 illustrates a schematic diagram of the mapping between optical responses and geometrical parameters of a reference model according to an embodiment of the present disclosure;

FIG. 6 illustrates a schematic diagram of a method for generating simulated dispersion curve data according to an embodiment of the present disclosure;

FIG. 7 illustrates a comparative plot of dispersion curve data generated according to conventional simulations and the neural network model of the present disclosure respectively;

FIG. 8 illustrates a slice plot of simulated dispersion curve data respectively generated according to the neural network model of the present disclosure;

FIG. 9 illustrates a comparative schematic diagram of a measured dispersion curve graph and a simulated dispersion curve graph according to an embodiment of the present disclosure;

FIG. 10 illustrates a comparative schematic diagram of measurement results of a measuring object solved according to the method of the present disclosure;

FIG. 11 illustrates a comparative plot of measurement results based on the method of AFM measurement and measurement results of the method of optical measurement of the present disclosure;

FIG. 12 illustrates a flowchart of a method for computing geometrical parameters of a measuring object according to an embodiment of the present disclosure;

FIG. 13 schematically illustrates a block diagram of an electronic device suitable for implementing an embodiment of the present disclosure.

### DETAILED DESCRIPTION OF EMBODIMENTS

Embodiments of the present disclosure will be described in more details below with reference to the drawings. Although the drawings illustrate certain embodiments of the present disclosure, it should be appreciated that the present disclosure can be implemented in various manners and should not be constructed as limited to the embodiments set forth herein. On the contrary, the embodiments are provided for a more thorough and complete understanding of the present disclosure. It should be understood that the drawings and embodiments of the present disclosure are for illustrative purposes only and are not intended to limit the scope of the present disclosure.

As described above, the conventional optical measurement schemes for a measuring object (such as the grating) requires a large amount of computations and takes a long time due to the need of performing analog computations on all the parameters in the spatial range of the geometric model, and the geometric model having a large span variation range for each parameter being easily restricted by the size of the database when solving geometric parameters of the measuring object. As a result, it has the disadvantages of complex computation and low measurement efficiency.

To at least partially address one or more of the above problems and other potential problems, exemplary embodiments of the present disclosure provide a scheme for optical measurement. The scheme comprises: generating input data for inputting to a neural network model based on coordinate data of dispersion curve data and preset values of geometric parameters with respect to a reference model; extracting features of the input data based on the neural network model trained via a plurality of samples, so as to generate simulated dispersion curve data associated with the preset values of the geometric parameters, the simulated dispersion curve data indicating a plurality of optical responses corresponding to a plurality of coordinate data of the dispersion curve data; obtaining measured dispersion curve data in relation to a measuring object; calculating a distance of the measured dispersion curve data from the simulated dispersion curve data, so as to determine whether the distance meets a predetermined condition; and in response to determining the distance does not meet the predetermined condition, determining a gradient for updating the preset values of the geometric parameters with respect to the reference model based on the distance, so as to regenerate simulated dispersion curve data via the neural network model based on the updated preset values to recalculate the distance.

In the above scheme, the present disclosure implements the mapping between the geometric parameters of the reference model and the simulated dispersion curve data via the neural network model, so that the mapping relationship between the geometric parameters of the reference model and the simulated dispersion curve data can be described with fewer trained parameters. This requires shorter time and does not require a large amount of computations compared to the conventional method of performing analog computations for all the parameters in the spatial range of the reference model. In addition, the present disclosure enables gradient optimization on model space by determining a gradient for updating preset values of geometric parameters with respect to a reference model based on a distance between the measured dispersion curve data and the simulated dispersion curve data, such that an optimal solution can be solved on a gradient basis in large solution space. Therefore, the present disclosure may rapidly and accurately determine the measurement results even for the measuring object having a wide range of parameters, relative to the conventional method of searching for close values in a huge database. Thus, the present disclosure enables accurate and rapid measurement on the measuring object.

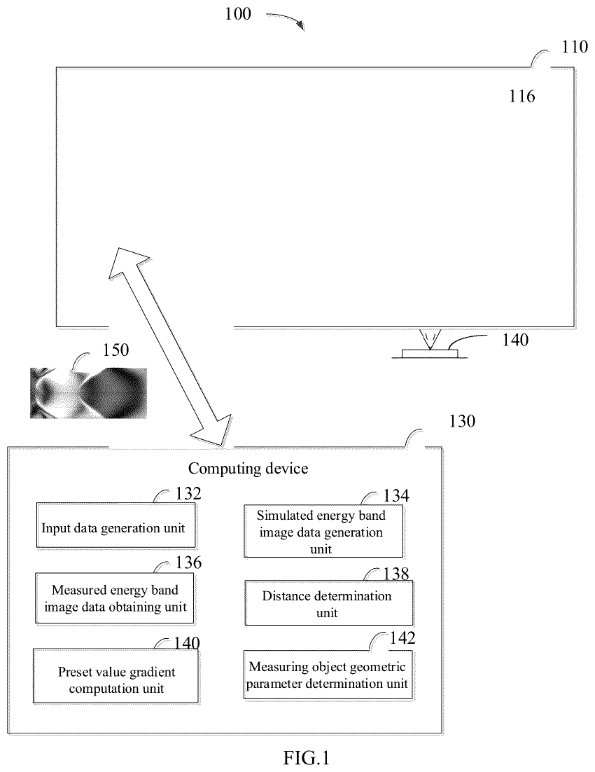

FIG. 1 illustrates a schematic diagram of an example system 100 that can be used for a method of optical measurement according to an embodiment of the present disclosure. As shown in FIG. 1, the system 100 includes a spectral measurement device 110, a computing device 130 and a measuring object 140.

With respect to the spectral measurement device 110, it may be, for example, an angle-resolved spectrometry. In particular, it may be a reflective angle-resolved spectrometry. The spectral measurement device 110 may generate a dispersion relation pattern 150 in momentum space based on the actual measurement of the measuring object 140 by the incident light, and the dispersion relation pattern 150 indicates at least dispersion curve data relating to the key parameters of the measuring object 140. A schematic configuration of the spectral measurement device 110, such as a reflective angle-resolved spectrometry, is further illustrated in FIG. 1. The reflective angle-resolved spectrometry is a momentum space spectral imaging technique based on Fourier optics. As shown in FIG. 1, the reflective angle-resolved spectrometry mainly includes an imaging optical path part and a spectral analysis part.

In the imaging part, light (such as natural light) is incident on a surface of the measuring object 140 by an illumination light source 116 passing through a polarizer 114 and being converged by an objective lens 112. The reflected light of the measuring object 140 passes through the objective lens 112 again, and a Fourier image of the measuring object 140 is obtained at aback focal plane of the objective lens 112. The remaining imaging optical path images the Fourier image at the back focal plane of the objective lens to the spectral analysis part.

The spectral analysis part may essentially include a spectrometry 120, an imager 122, such as a 2-dimensional CCD array, and a slit 118. The slit 118 is used for selecting momentum coordinates that need spectral analysis on the Fourier image of the measuring object. For the Fourier image (alternatively referred to as inverse spatial image, momentum spatial image), the momentum coordinates are represented, for example, as kx and ky. Here, it can be expanded at any ky. Assuming that it requires to expand at ky=0. The slit 118 can be closed to a minimum and aligned with a corresponding linear position of the Fourier image at ky=0, so as to screen the momentum coordinates entering the spectrometry. The linear Fourier image filtered after entering the spectrometry will be expanded by wavelength, forming a two-dimensional image and recorded on an imager such as a 2-dimensional CCD array.

Byway of example only, the types of the above-mentioned light source, objective lens, and spectrometry of the present disclosure may be as follows:

Objective lens: MplanFLN 100X @Olympus; light source: U-LH100L-3 @Olympus; spectrometry: HRS-300 @Princeton Instrument; CCD: PIXIS: 1024 @Princeton Instrument. In addition, a silver mirror (ME05S-P01@Thorlabs) is needed as an accessory.

Assume an etched grating sample is to be measured. The direction in which the grating periodically changes is referred to as a kx direction, and the direction of the groove of the grating is referred to as a ky direction. Thereby, measure the dispersion relation pattern in momentum space at a predetermined ky, wherein a dispersion curve is formed in the dispersion relation pattern, and wherein the dispersion curve reflects the key parameters of the measuring object. In terms of optical representation, the dispersion curve is the variation trajectory of the eigenvalues of the optical eigen-equation in momentum space. Merely by way of example, the dispersion relation pattern in momentum space of the grating sample to be measured along the direction of ky=0 direction under the irradiation of light s and p can be measured.

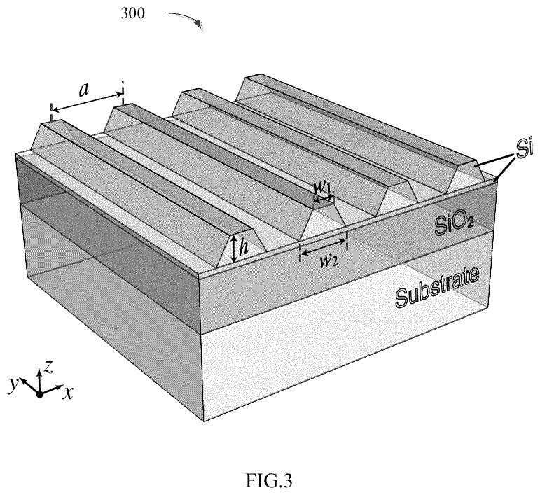

With respect to the measuring object 140, it may be, for example but not limited to, the etched grating. As an example of the measuring object 140, FIG. 3 depicts an etched grating as a model of the measuring object, wherein the cross-sectional shape of the etched grating is shown as an isosceles trapezoid, and the structure of the grating can be described with four key parameters: upper base of the trapezoid w1, lower base of the trapezoid w2, etching depth h and period a of the grating. Be noted that the four key parameters are for example only. In terms of the contour of the grating, and other key parameters, such as angle of inclination of the sidewall, may also be included.

With respect to the computing device 130, it is used for training the neural network model for generating simulated dispersion curve data based on a plurality of samples; generating input data based on coordinate data of dispersion curve data and preset values of geometric parameters with respect to a reference model; inputting the input data into a trained neural network model to generate simulated dispersion curve data associated with the preset values of the geometric parameters; calculating a distance of the measured dispersion curve data from the simulated dispersion curve data, so as to determine whether the distance meets a predetermined condition; and in the case of the determination that the distance does not meet the predetermined condition, determining a gradient for updating the preset values of the geometric parameters with respect to the reference model based on the distance, so as to regenerate simulated dispersion curve data via the neural network model based on the updated preset values to recalculate the distance; and if determining the distance meets the predetermined condition, determining the geometric parameters of the measuring object based on preset values corresponding to the input data for generating the current simulated dispersion curve data.

The computing device 130 may have one or more processing units, including specific purpose processing units such as GPU, FPGA, ASIC, and the like, as well as general purpose processing units such as CPU. In addition, one or more virtual machines may also run on each computing device 130. The computing device 130 includes, for example, an input data generation unit 132, a simulated dispersion curve data generation unit 134, a measured dispersion curve data generation unit 136, a distance determination unit 138, a preset value gradient computation unit 140 and a measuring object geometric parameter determination unit 142.

With respect to the input data generation unit 132, it generates input data for inputting to a neural network model based on coordinate data of dispersion curve data and preset values of geometric parameters with respect to a reference model.

With respect to the simulated dispersion curve data generation unit 134, it extracts features of the input data based on the neural network model trained via a plurality of samples, so as to generate simulated dispersion curve data associated with the preset values of the geometric parameters, the simulated dispersion curve data indicating a plurality of optical responses corresponding to a plurality of coordinate data of the dispersion curve data.

With respect to the measured dispersion curve data generation unit 136, it obtains the measured dispersion curve data in relation to a measuring object.

With respect to the distance determination unit 138, it calculates the distance of the measured dispersion curve data from the simulated dispersion curve data, so as to determine whether the distance meets a predetermined condition.

With respect to the preset value gradient computation unit 140, it is used for, in response to determining the distance does not meet the predetermined condition, determining a gradient for updating the preset values of the geometric parameters with respect to the reference model based on the distance, so as to regenerate simulated dispersion curve data via the neural network model based on the updated preset values to recalculate the distance.

With respect to the measuring object geometric parameter determination unit 142, it is used for, in response to determining the distance does not meet the predetermined condition, determining a gradient for updating the preset values of the geometric parameters with respect to the reference model based on the distance, so as to regenerate simulated dispersion curve data via the neural network model based on the updated preset values to recalculate the distance.

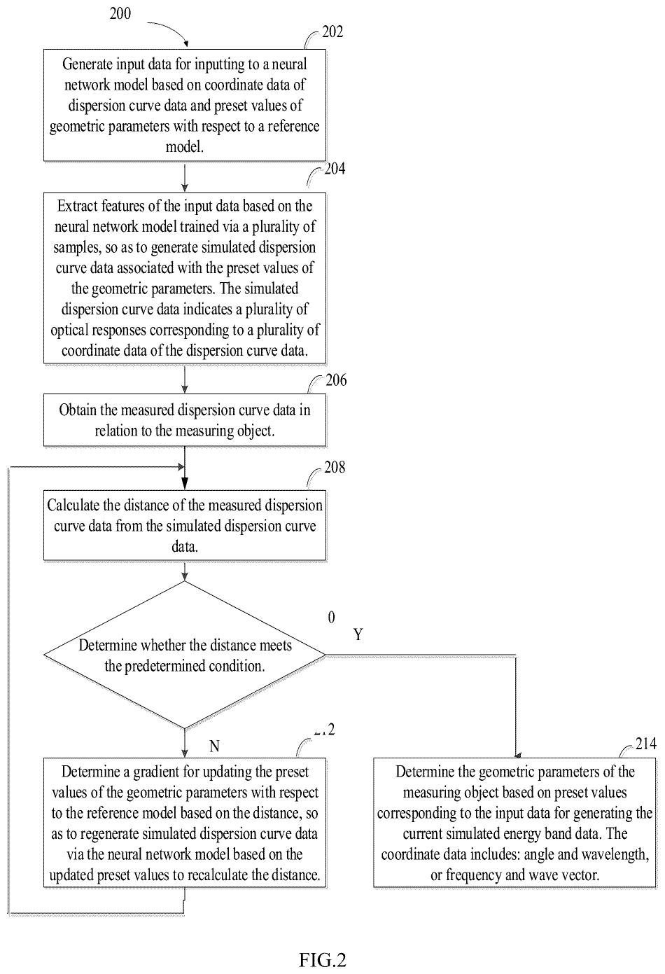

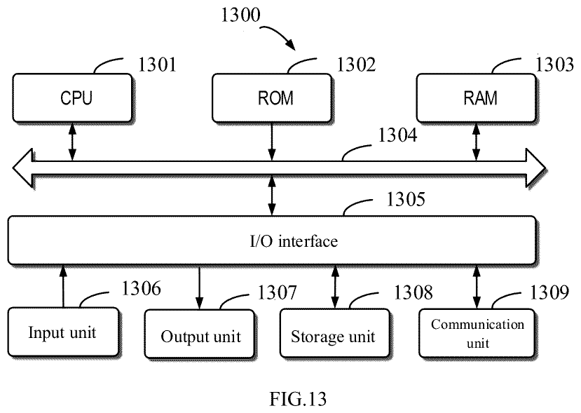

A method 200 for optical measurement will be described in detail below in conjunction with FIG. 2, FIG. 3, and FIG. 5 to FIG. 8. FIG. 2 illustrates a flowchart of a method 200 for optical measurement according to an embodiment of the present disclosure. It should be appreciated that the method 200 may be performed, for example, at an electronic device 1300 depicted in FIG. 13. It may also be performed at the computing device 130 depicted in FIG. 1. It should be understood that method 200 may also include additional components and actions not shown and/or may omit components and actions shown. The scope of the present disclosure is not limited in this respect.

At step 202, the computing device 130 generates input data for inputting to a neural network model based on coordinate data of dispersion curve data and preset values of geometric parameters with respect to a reference model.

With respect to the reference model, it is used to provide a modeling basis for establishing a mapping relationship between the geometric parameters and the simulated dispersion curve data. The reference model is, for example and without limitation, the reference model 300 shown in FIG. 3. FIG. 3 illustrates a schematic diagram of a reference model according to an embodiment of the present disclosure. As shown in FIG. 3, the reference model 300 is, for example, an isosceles trapezoid. The geometric parameters of the reference model 300 include, for example, upper base of the trapezoid w1, lower base of the trapezoid w2, period a of the grating and etching depth h. In some embodiments, the upper base of the trapezoid w1 or the lower base of the trapezoid w2 ranges, for example, from 150 nm to 380 nm. The period a of the grating ranges, for example, from 380 nm to 520 nm.

With respect to the neural network model, it is used to generate the simulated dispersion curve data. The neural network model may be constructed based on, for example, python (e.g., version 3.6.8), tensorflow-Gpu (e.g., version 1.13.1), or cuda (e.g., version 10.0). By way of example, the neural network model includes, for example, but is not limited to, 17 layers of network. Each layer of network has, for example, 60 neurons. Each layer of neural network employs, for example, leaky relu function as non-linear function. A shortcut is configured between every two layers of network, so as to form a residual block. Thereby improving the network performance of the neural network model.

With respect to the input data of the neural network model, it is, for example, generated based on the geometric parameter of the reference model and the coordinate data of the simulated dispersion curve data (e.g., the simulated dispersion curve graph). For example, the input data is six parameters, wherein the first four parameters are geometric parameters of the reference model 300, such as the upper base of the trapezoid w1, the lower base of the trapezoid w2, the period a of the grating, the etching depth h; and the last two parameters of the input data are the coordinate data on the simulated dispersion curve graph. The coordinate data, for example, includes: the angle and the wavelength, or the frequency and the wave vector.

With respect to the output data of the neural network model, it is, for example, the plurality of optical responses corresponding to the plurality of coordinate data of the dispersion curve data. For example, the output data is one or more parameters such as reflectivity corresponding to the geometric parameters of the reference model and the coordinate data of the simulated dispersion curve data.

At step 204, the computing device 130 extracts features of the input data based on the neural network model trained via a plurality of samples, so as to generate simulated dispersion curve data associated with the preset values of the geometric parameters. The simulated dispersion curve data indicates a plurality of optical responses corresponding to a plurality of coordinate data of the dispersion curve data.

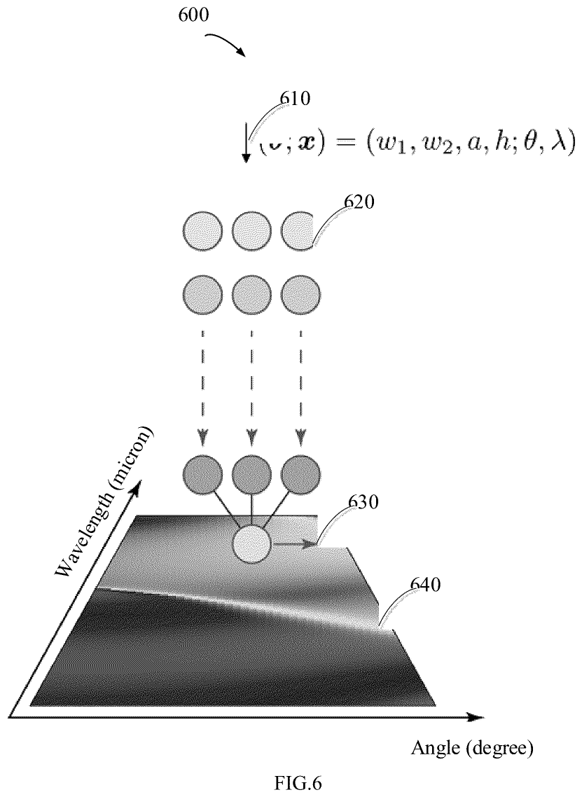

A method of generating the simulated dispersion curve data will be described below in conjunction with FIG. 5 and FIG. 6. FIG. 5 illustrates a schematic diagram of the mapping between optical responses and geometrical parameters of a reference model according to an embodiment of the present disclosure. As shown in FIG. 5, reference number 510 represents geometric parameter space of the reference model. Reference number 520 represents optical parameter space of the reference model. Reference number 530 represents the neural network model trained by a plurality of samples. A solid line 532 represents forward mapping of the geometric parameters of the reference model to the optical responses via the neural network model. A dashed line 534 represents solving the geometric parameters of the reference model by the optical responses.

FIG. 6 illustrates a schematic diagram of a method 600 for generating simulated dispersion curve data according to an embodiment of the present disclosure. The input data (θ; x)=(w₁, w₂, a, h; θ, λ), for example, includes four geometric parameters (e.g., upper base of the trapezoid w1, lower base of the trapezoid w2, period a of the grating, and etching depth h), and two coordinate data (e.g., angle θ and wavelength λ). The input data is input to a neural network model 620 to generate output data 630. The output data is an optical parameter (e.g., emissivity) corresponding to the two coordinate data. Here, a measurement range of the angle θ is from 0 to 50 degree, and a measurement range of the wavelength λ is from 1 to 1.6 micron, for example. The computing device 130, for example, changes the angle θ at an interval of one degree and changes the wavelength λ at an interval of three nanometers. For the upper base of the trapezoid w1, the lower base of the trapezoid w2, the period a of the grating, the etching depth h, and the angle θ and the wavelength λ of each change, a corresponding point on two-dimensional dispersion curve data 640, i.e., optical parameter corresponding to the angle and the wavelength coordinate, is generated via the neural network model 620. Based on the angle θ varying between 0 and 50 degree, and the wavelength λ varying between 0.9 and 1.7 microns, the two-dimensional dispersion curve data 640 as shown in FIG. 6 can be generated, where the abscissa is the angle and the ordinate is the wavelength.

In some embodiments, the simulated dispersion curve data includes the thin film interference portion indicating the smooth change and the grating energy band portion indicating the abrupt-sharp change.

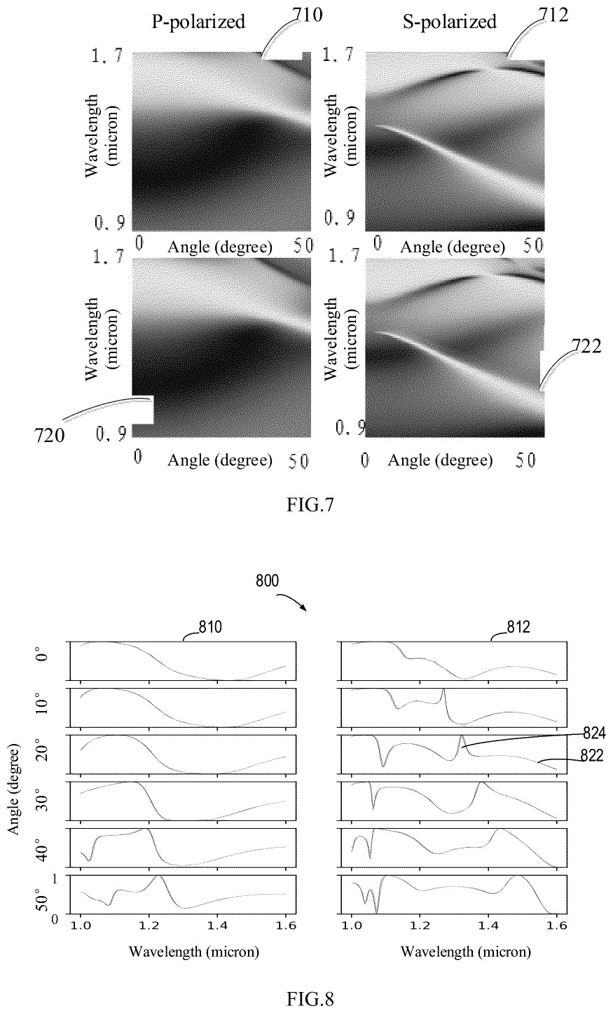

FIG. 7 illustrates a comparative plot of dispersion curve data generated according to conventional simulations and the neural network model of the present disclosure respectively. As shown in FIG. 7, reference number 710 indicates the dispersion curve data under the P-polarized light generated via conventional analog computations, and reference number 720 indicates the simulated dispersion curve data under the P-polarized light generated via the neural network model of the present disclosure. Reference number 712 indicates the dispersion curve data under the S-polarized light generated via conventional analog computations, and reference number 722 indicates the simulated dispersion curve data under the S-polarized light generated via the neural network model of the present disclosure.

FIG. 8 illustrates a slice plot of simulated dispersion curve data respectively generated according to the neural network model of the present disclosure. FIG. 8 shows a slice plot 810 for the simulated dispersion curve data under the P-polarized light in units of every 10 degrees, and a slice plot 812 for the simulated dispersion curve data under the S-polarized light in units of every 10 degrees. Take the slice plot 812 of the simulated dispersion curve data under the S-polarized light as an example. The simulated dispersion curve data generated via the neural network model of the present disclosure comprises a thin film interference portion 822 which is indicative of a smooth change and a grating energy band portion 824 which is indicative of an abrupt-sharp change. By adopting the means described above, the present disclosure can rapidly generate an accurate simulated dispersion curve graph. In addition, since optical responses corresponding to each wavelength and angle coordinate data may be generated point-by-point via the neural network model to form the simulated dispersion curve graph based on a plurality of optical responses corresponding to a plurality of coordinate data, the present disclosure may enable the simulated dispersion curve graph to include a sharp abrupt grating energy band portion, whereas a conventional simulated dispersion curve graph generated based on a simulation algorithm may not accurately generate the sharp abrupt grating energy band portion due to the correlation between successive points.

There are many ways to train the neural network model. In some embodiments, the plurality of samples used to train the neural network model are generated based on a rigorous coupled wave analysis algorithm or a finite difference time domain algorithm. With regard to the parameter ranges, parameter ranges of the four geometric parameters are determined by the structural parameter ranges of the reference model. The parameter range of the coordinate data on the simulated dispersion curve graph is determined, for example, based on the measurement range of the angle-resolved spectrum, e.g., the parameter range for the wavelength is 0.9 to 1.7 microns, and the parameter range for the angle is 0 to 50 degrees. For example, the computing device 130 randomly samples in parameter ranges of six parameters to generate a set of data sample training data. Each sample data includes six input parameters and reflectivity values corresponding to the input parameters. For example, 10000 input parameters and reflectivity values corresponding to these input parameters are computed by random sampling and then stored in a file.

During the training of the neural network model, the computing device 130 is trained, for example, using an Adam stochastic gradient descent method. The reason of using Adam stochastic gradient descent method is that it has high computational efficiency, can adapt to a large data set, and has desired result. For example, the learning rate is configured to be 0.001 and is reduced to 1/10 every 100 rounds of training. The neural network model has undergone 500 rounds of training, with a training time of approximately 5 hours, for example. After the training of the neural network model is completed, the computing device 130 fixes the parameters of the neural network model so as to use the neural network model to solve the geometric parameters of the measuring object.

As to the method of generating the simulated dispersion curve data, it includes, for example: based on predetermined geometric parameters with respect to the reference model and coordinate data of the dispersion curve data varying within a predetermined range, generating reflectivity data corresponding to each coordinate data varying within the predetermined range via the neural network model; and generating the simulated dispersion curve data based on the each coordinate data varying within the predetermined range and reflectivity data corresponding to the each coordinate data. In the conventional method that directly mapping to the dispersion curve graph using model parameters, it is difficult to accurately generate a sharp abrupt grating energy band portion because of the strong correlation between points. In contrast, the present disclosure generates the simulated dispersion curve data point-by-point based on each coordinate data varying within the predetermined range and reflectivity data corresponding to the each coordinate data, and thus the present disclosure may enables accurate generation of sharp abrupt grating energy band portion in the simulated dispersion curve graph. In addition, the neural network model of the present disclosure generates the energy band point-by-point based on the coordinate data, and thus the volume of the neural network model is very small. Storage space occupied by a packaged neural network model is only about 1 MB, which is far smaller than the scale of the network required to generate the simulated dispersion curve graph directly.

At step 206, the computing device 130 obtains the measured dispersion curve data in relation to the measuring object. As mentioned above, the measured dispersion curve data is, for example, the dispersion relation pattern in momentum space generated by the spectral measurement device 110 based on the actual measurement of the measuring object 140 by the incident light. In some embodiments, after the computing device 130 obtaining the dispersion curve data from the spectral measurement device 110, a measured grating sample dispersion curve is converted to a measured dispersion curve data at a momentum-wavelength coordinate, or an angle-wavelength coordinate according to a momentum-angle conversion equation and an Abbe's sine condition. In some embodiments, the computing device 130 may also subject the obtained measured dispersion curve data to image smoothing and down-sampling processing prior to the process at step 208.

With respect to the method of measuring the dispersion curve data of the measuring object, in some embodiments, in order to improve accuracy of the obtained dispersion relation pattern of the measuring object in the momentum space, when measuring the dispersion curve data, it is necessary to consider effects of both the dispersion curve graph of the momentum space of the background of the measuring object and the dispersion curve graph of the momentum space of the light source on the dispersion curve graph of the measuring object in the momentum space. Accordingly, the spectral measurement device 110 may obtain the dispersion curve graph of the measuring object in momentum space under irradiation of incident light (e.g., polarized light) based on the measured dispersion curve data of momentum space of the background in which the measuring object is located, the dispersion curve data of momentum space of a light source, and the measured initial dispersion curve data of momentum space of the measuring object. For example, the spectral measurement device 110 sequentially measures the dispersion curve graph I_{background,m} of momentum space of the background in which the measuring object is located, the dispersion curve graph I_{source,m} of momentum space of the light source, and the measured initial dispersion curve graph I_{sample,m} of momentum space of the measuring object, and then the dispersion curve graph Iₛₐₘₚₗₑ of the measuring object in momentum space considering the above-mentioned effects can be expressed as follows:

$${I}_{sample} = \frac{{I}_{sample , m} - {I}_{background , m}}{{I}_{source , m} - {I}_{background , m}} \qquad ( 1 )$$

As an example, first, a momentum space image I_{background,m} in the background can be measured with the objective lens against an empty objective stage. Then, place the silver mirror on the objective stage, measuring a momentum space image I_{source,m} of the light source, where it is necessary to focus the objective lens on the surface of the silver mirror for measuring the silver mirror, and a diaphragm can be used to help focusing. Later, place the measuring object and adjust the surface of the measuring object to be horizontal. The grating direction is along the ky=0 direction and the objective lens is focused on the sample surface, and measure a momentum space image I_{sample,m} of the measuring object. Then, the dispersion curve graph Iₛₐₘₚₗₑ of the measuring object in momentum space under irradiation of incident light (e.g., polarized light) is obtained according to the above exemplary Equation (1).

In some embodiments, the measurement background may be a dark background, i.e., the background signals received by a detector in the absence of input signals.

In some embodiments, in the case of a plurality of samples to be measured, the background and the light source need only to be measured once. While when switching the polarization of the incident light, the background and the light source need to be re-measured due to the effect of the polarizer. In still other embodiments, if no polarizer is used, or the polarizer is fixed, there is no need to change the measuring system.

At step 208, the computing device 130 calculates the distance of the measured dispersion curve data from the simulated dispersion curve data.

With regard to the distance calculation method, it is, for example, that the computing device 130 calculates the Euclidean distance between the measured dispersion curve data and the simulated dispersion curve data. The method of calculating the Euclidean distance between the measured dispersion curve data and the simulated dispersion curve data is described below in conjunction with Equation (2).

C(Rₛᵢₘ,Rₑₓₚ)=Σ_{i,j}[Rₛᵢₘ(i,j)−Rₑₓₚ(i,j)] (2)

In Equation (2) above, Rₛᵢₘ(i,j) represents the simulated dispersion curve data (e.g., apparent dispersion curve graph) generated by the neural network model. Rₑₓₚ(i,j) represents the measured dispersion curve data. i, j represents the coordinate data of the dispersion curve data. C(Rₛᵢₘ, Rₑₓₚ) represents the Euclidean distance between the measured dispersion curve data and the simulated dispersion curve data.

At step 210, the computing device 130 determines whether the distance meets the predetermined condition.

With respect to the predetermined condition, it includes, for example, one of the followings: the Euclidean distance between the measured dispersion curve data and the simulated dispersion curve data is the smallest; and the Euclidean distance between the measured dispersion curve data and the simulated dispersion curve data is less than a predetermined threshold.

At step 212, if the computing device 130 determines that the distance does not meet the predetermined condition, determining a gradient for updating the preset values of the geometric parameters with respect to the reference model based on the distance, so as to regenerate simulated dispersion curve data via the neural network model based on the updated preset values to recalculate the distance. For example, after regenerating a simulated dispersion curve data at step 212, return back to step 208 and calculate the distance between the measured dispersion curve data and the simulated dispersion curve data regenerated at step 212. Then, at step 210, determine whether the recalculated distance meets the predetermined condition. If the recalculated distance still does not meet the predetermined condition, repeat the step at step 212 until the distance meets the predetermined condition.

With respect to the determination method of the gradient of the preset values, it includes, for example: the computing device 130 determines the gradient for updating the preset values of the geometric parameters with respect to the reference model based on the distance between the measured dispersion curve data and the simulated dispersion curve data calculated at step 208. For example, the gradient for change in the parameter space of the reference model to which the distance function corresponds is computed by the neural network model.

With respect to the method of updating the gradient of the preset values for regenerating the simulated dispersion curve data, it includes, for example: the computing device 130 determines the gradient for updating the preset values of the geometric parameters with respect to the reference model based on the distance; the preset values of the geometric parameters with respect to the reference model based on the gradient, so as to generate updated input data based on the updated preset values; and input the updated input data to the neural network model, and regenerating simulated dispersion curve data associated with the updated preset value.

With respect to the algorithm for updating the gradient for the preset values, it may include various kinds. For example, Newton method, Gauss-Newton iteration method, greedy algorithm, or a combination of the above algorithms may be used to update the gradient of the preset values. The basic concept of Newton method is to use a polynomial function to approximate a given function value, and then find the estimated value of the minimum point. Using Newton method to update the gradient of the preset values, fast convergence speed is obtained. Gauss-Newton iterative method is an improvement of Newton method, which uses Taylor series expansion to approximately replace a nonlinear regression model. Then, a regression coefficient is modified many times through many iterations so that the regression coefficient continues to approach the best regression coefficient of the nonlinear regression model, and finally to minimize a residual sum of squares of the initial model. At step 214, if the computing device 130 determines that the distance meets the predetermined condition, determining the geometric parameters of the measuring object based on preset values corresponding to the input data for generating the current simulated dispersion curve data. The coordinate data includes: angle and wavelength, or frequency and wave vector.

For example, conduct a forward mapping by the updated geometric parameters of the reference model via the neural network model, regenerate the simulated dispersion curve data (e.g., the dispersion curve graph), and recalculate the distance between the measured dispersion curve data and the simulated dispersion curve data to determine whether the distance meets the predetermined condition. The geometric parameters of the reference model are updated by circulating the above process, for example, through 200 rounds of the above cycle, the learning rate of the updating is initially as 0.02, and becomes 1/10 every 100 rounds. Determine the distance between the measured dispersion curve data and the current simulated dispersion curve data meets the predetermined condition. For example, the distance is the smallest, indicating that the measured dispersion curve data has the best consistency with the current simulated dispersion curve data. Then determine the geometric parameters of the measuring object based on the preset values of the geometric parameters of the reference model corresponding to the input data used for generating the current simulated dispersion curve data. The determined geometric parameters may be output as the measurement result of the measuring object. In some embodiments, the computing device 130 also outputs a comparative plot of the measured dispersion curve data and the simulated dispersion curve data corresponding to the minimum distance. In the above scheme, the present disclosure implements the mapping between the geometric parameters of the reference model and the simulated dispersion curve data via the neural network model, so that the mapping relationship between the geometric parameters of the reference model and the simulated dispersion curve data can be described with fewer trained parameters. This requires shorter time and does not require a large amount of computations compared to the conventional method of performing analog computations for all the parameters in the spatial range of the reference model. In addition, the present disclosure enables gradient optimization on model space by determining a gradient for updating preset values of geometric parameters with respect to a reference model based on a distance between the measured dispersion curve data and the simulated dispersion curve data, such that an optimal solution can be solved on a gradient basis in large solution space. Therefore, the present disclosure may rapidly and accurately determine the measurement results even for the measuring object having a wide range of parameters, relative to the conventional method of searching for close values in a huge database. Thus, the present disclosure enables accurate and rapid measurement on the measuring object.

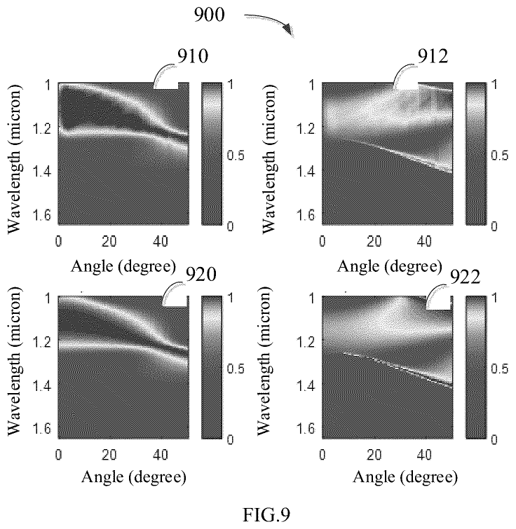

FIG. 9 illustrates a comparative schematic diagram of a measured dispersion curve graph and a simulated dispersion curve graph according to an embodiment of the present disclosure. Here, as shown in FIG. 9, reference number 910 indicates the measured dispersion curve graph under the P-polarized light. Reference number 920 indicates the simulated dispersion curve graph under the P-polarized light selected by determining the minimum corresponding distance. Reference number 912 indicates the measured dispersion curve graph under the S-polarized light. Reference number 922 indicates the simulated dispersion curve under the S-polarized light selected by determining the minimum corresponding distance.

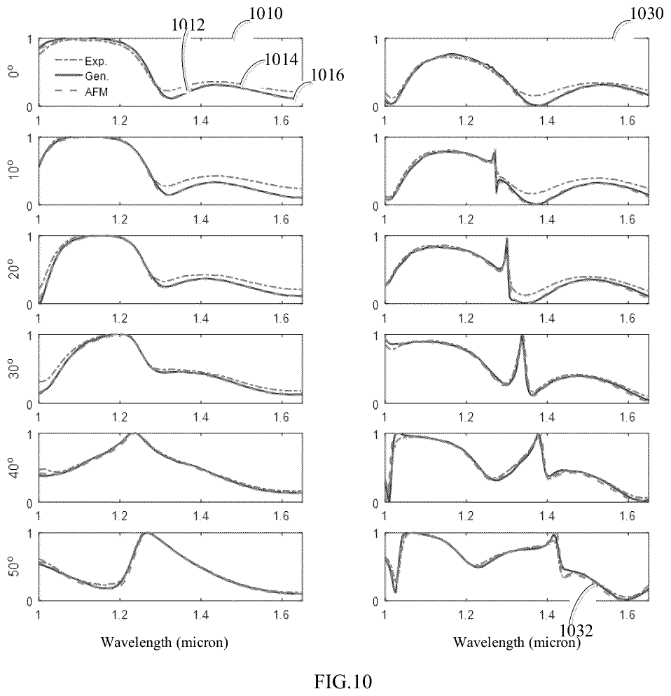

FIG. 10 illustrates a comparative schematic diagram of measurement results of a measuring object solved according to the method of the present disclosure. Reference number 1010 indicates comparison of slice images of the measured dispersion curve graph (represented by an abbreviation Exp in FIG. 10), the target simulated dispersion curve graph (i.e., the simulated dispersion curve corresponding to a minimum distance from the measured dispersion curve graph, represented by an abbreviation Gen in FIG. 10), and the AFM measured dispersion curve graph (represented by an abbreviation AFM in FIG. 10) under the P-polarized light. Reference number 1030 indicates comparison of the slice images of the measured dispersion curve graph, the target simulated dispersion curve graph and the AFM measured dispersion curve graph under the S-polarized light. A dashed line 1014 with small intervals indicates a slice image of the experimental-measured dispersion curve graph. A solid line 1016 indicates a slice of the dispersion curve graph corresponding to the optimal solution (minimum distance from the measured dispersion curve graph) for the geometric parameters of the measuring object found using the method of the present disclosure. A dashed line 1012 with large intervals (or a dashed line 1032 with large intervals) indicates a slice of the dispersion curve graph computed by a RCWA algorithm after using the geometric parameters obtained by the AFM measurement method.

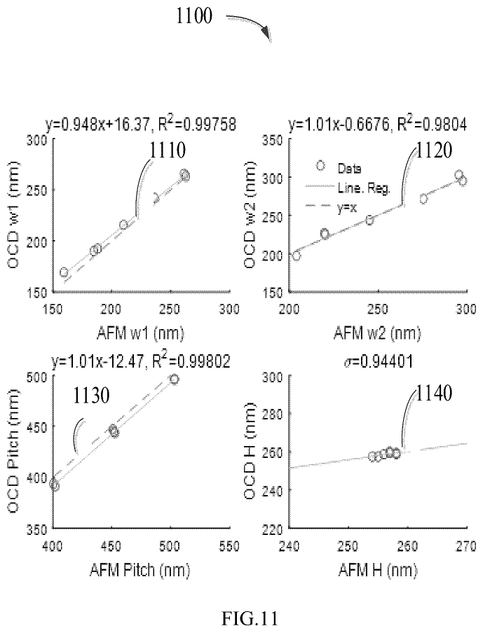

FIG. 11 illustrates a comparative plot of measurement results based on the method of AFM measurement and measurement results of the method of optical measurement of the present disclosure. Comparing the measurement result of the AFM measurement method with the measurement result of the optical measurement method of the present disclosure on a plurality of grating areas on the same measuring object. Taking the measurement results obtained by the AFM measurement method as abscissa data and the measurement results obtained by the optical measurement method of the present disclosure as ordinate data, and performing linear regression on the two methods. In this case, the three parameters of the upper base of the trapezoid w1, the lower base of the trapezoid w2, the period a of the grating all reach high consistency R2 (0.980-0.999). In addition, since the etching depth h of the same measuring object tends to be very close, if only discuss the variance of the etching depth h, the variance of the etching depth h results in less than one nanometer. In addition, a solving process for solving the geometric parameters of the measuring object using the method of the present disclosure takes about 20 seconds. Thus, the present disclosure enable accurate and rapid measurement on measuring object such as the grating.

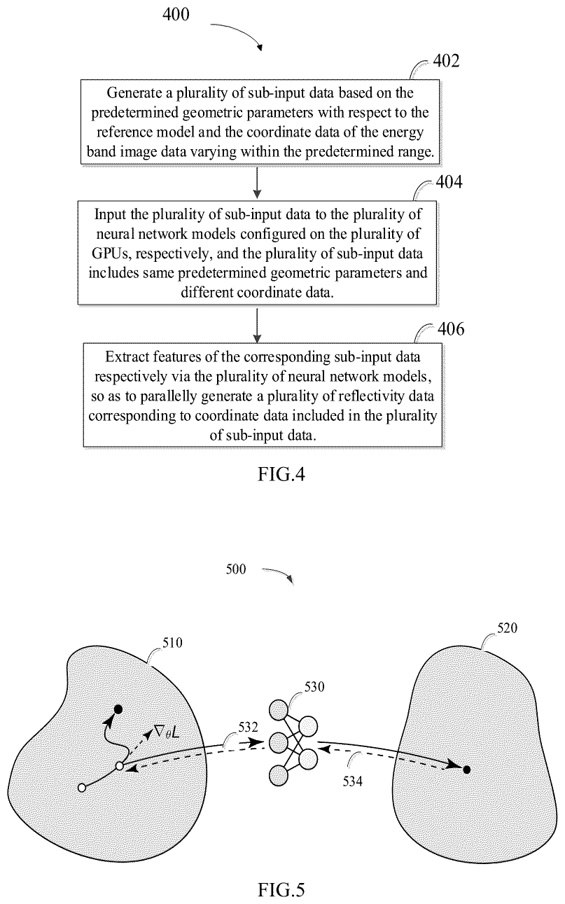

FIG. 4 illustrates a flowchart of a method 400 for generating reflectivity data corresponding to the coordinate data varying within a predetermined range according to an embodiment of the present disclosure. It should be appreciated that the method 400 may be performed, for example, at the electronic device 1300 depicted in FIG. 13. It may also be performed at the computing device 130 depicted in FIG. 1. It should be appreciated that the method 400 may also include additional components and actions not shown and/or may omit components and actions shown. The scope of the present disclosure is not limited in this respect.

At step 402, the computing device 130 generates a plurality of sub-input data based on the predetermined geometric parameters with respect to the reference model and the coordinate data of the dispersion curve data varying within the predetermined range.

At step 404, the computing device 130 inputs the plurality of sub-input data to the plurality of neural network models configured on the plurality of GPUs, respectively, and the plurality of sub-input data includes same predetermined geometric parameters and different coordinate data.

At step 406, the computing device 130 extracts features of the corresponding sub-input data respectively via the plurality of neural network models, so as to parallelly generate a plurality of reflectivity data corresponding to coordinate data included in the plurality of sub-input data.

By adopting the above-mentioned means, the present disclosure can generate the reflectivity data corresponding to the coordinate data in parallel, which facilitates the rapid generation of the simulated dispersion curve graph, so as to rapidly solve the measurement result of the measuring object.

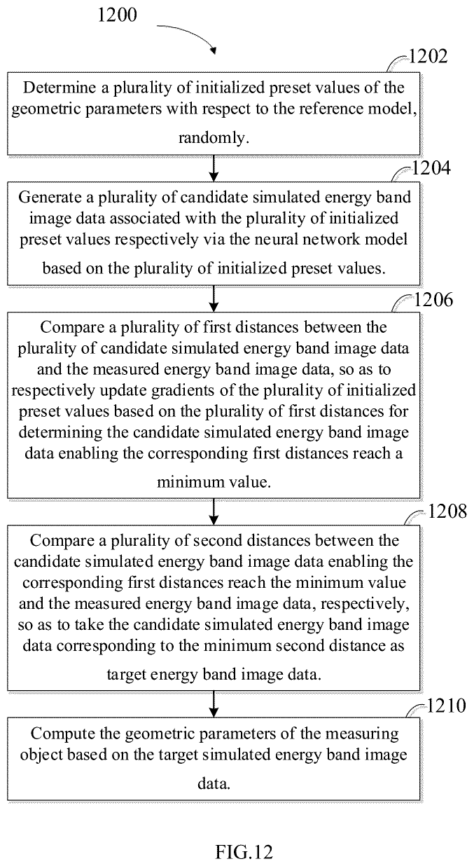

In some embodiments, in order to prevent the algorithm from converging to a local optimum, the method 200 also includes a method 1200 for generating the simulated dispersion curve data. FIG. 12 illustrates a flowchart of a method 1200 for computing geometrical parameters of a measuring object according to an embodiment of the present disclosure. It should be appreciated that the method 1200 may be performed, for example, at the electronic device 1300 depicted in FIG. 13. It may also be performed at the computing device 130 depicted in FIG. 1. It should be appreciated that method 1200 may also include additional components and actions not shown and/or may omit components and actions shown. The scope of the present disclosure is not limited in this respect.

At step 1202, the computing device 130 randomly determines a plurality of initialized preset values of the geometric parameters with respect to the reference model. For example, the computing device 130 randomly initializes N initialized preset values simultaneously within the parameter range of the geometric parameters with respect to the reference model. N is, for example and without limitation, chosen to be 15.

At step 1204, the computing device 130 generates a plurality of candidate simulated dispersion curve data associated with the plurality of initialized preset values respectively via the neural network model based on the plurality of initialized preset values. For example, the computing device 130 generates the input parameters for inputting to the neural network model based on the plurality of initialized preset values of the 15 above-mentioned geometric parameters and the coordinate data with respect to the reference model, and generates 15 candidate simulated dispersion curve data via the neural network model.

At step 1206, the computing device 130 compares a plurality of first distances between the plurality of candidate simulated dispersion curve data and the measured dispersion curve data, so as to respectively update gradients of the plurality of initialized preset values based on the plurality of first distances for determining the candidate simulated dispersion curve data enabling the corresponding first distances reach a minimum value. For example, calculating the Euclidean distances between the 15 candidate simulated dispersion curve data and the measured dispersion curve data, respectively, according to the aforementioned Equation (1). Then, determining respective gradients for updating the plurality of initialized preset values based on the respective Euclidean distances. Thereafter, updating the corresponding initialized preset value based on each gradient, and then recomputing the updated candidate simulated dispersion curve data via the neural network model based on the updated initialized preset values. Then, re-determiming respective gradients for updating the plurality of initialized preset values based on the plurality of the recomputed first distances, and so on and on, until the determination of the candidate simulated dispersion curve data enabling the corresponding first distance reach a minimum value. For example, after the completion of the respective 200 rounds of calculation, determining 15 candidate simulated dispersion curve data enabling the corresponding first distances reach the minimum value, respectively.

At step 1208, the computing device 130 compares a plurality of second distances between the candidate simulated dispersion curve data enabling the corresponding first distances reach the minimum value and the measured dispersion curve data, respectively, so as to take the candidate simulated dispersion curve data corresponding to the minimum second distance as target dispersion curve data. For example, the computing device 130 laterally compares magnitudes of the plurality of second distances between the 15 candidate simulated dispersion curve data enabling the corresponding first distances reach the minimum value and the measured dispersion curve data, and selects the candidate simulated dispersion curve data enabling the minimum second distance as the target dispersion curve data.

At step 1210, the computing device 130 computes the geometric parameters of the measuring object based on the target simulated dispersion curve data. For example, the computing device 130 selects a set of geometric parameters of the reference model with the smallest second distance function as the output of a final measurement result of the measuring object.

A research shows that, by using the above method, it takes about 20 seconds to solve the geometric parameters of the measuring object. It can be seen that the time consumed by the method disclosed in the present disclosure is much less than that by the conventional optical measurement method.

By using the above-mentioned technical means, the present disclosure can increase robustness of the measurement result, enabling the finally determined simulated dispersion curve graph closest to the measured dispersion curve graph and preventing the algorithm from converging to the local optimum.

FIG. 13 schematically illustrates a block diagram of an electronic device 1300 suitable for implementing embodiments of the present disclosure. The device 1300 may be a device for implementing the methods 200, 400, 600, and 1200 shown in FIG. 2, FIG. 4, and FIG. 6. As shown in FIG. 13, the device 1300 includes a central processing unit (CPU) 1301, which can execute various suitable actions and processes based on the computer program instructions stored in a read-only memory (ROM) 1302 or computer program instructions loaded to a random-access memory (RAM) 1303 from a storage unit 1308. The RAM 1303 can also store all kinds of programs and data required by the operations of the device 1300. The CPU 1301, the ROM 1302 and the RAM 1303 are connected to each other via a bus 1304. The input/output (I/O) interface 1305 is also connected to the bus 1304.

A plurality of components in the device 1300 is connected to the I/O interface 1305, including: an input unit 1306; an output unit 1307; a storage unit 1308. The processing unit 1301 performs the various methods and processes described above, such as performing the methods 200, 400, 600, and 1200. For example, in some embodiments, the methods 200, 400, 600, and 1200 can be implemented as a computer software program stored on the machine-readable medium, e.g., the storage unit 1308. In some embodiments, the computer program can be partially or fully loaded and/or mounted to the device 1300 via the ROM 1302 and/or the communication unit 1309. When the computer program is loaded to the RAM 1303 and executed by the CPU 1301, one or more operations of the above described methods can be implemented. Alternatively, in other embodiments, the CPU 1301 may be configured to perform one or more actions of the methods 200, 400, 600, and 1200 in any other suitable manner (e.g., by means of the firmware).

It should be further noted that the present disclosure can be methods, apparatuses, systems and/or computer program products. The computer program product may include a computer-readable storage medium, on which the computer-readable program instructions for executing various aspects of the present disclosure are loaded.

The computer-readable storage medium can be a tangible device that maintains and stores instructions utilized by the instruction executing device. The computer-readable storage medium can be, but not limited to, such as electrical storage device, magnetic storage device, optical storage device, electromagnetic storage device, semiconductor storage device or any appropriate combinations of the above. More concrete examples of the computer-readable storage medium (non-exhaustive list) include: portable computer disk, hard disk, random-access memory (RAM), read-only memory (ROM), erasable programmable read-only memory (EPROM or flash), static random-access memory (SRAM), portable compact disk read-only memory (CD-ROM), digital versatile disk (DVD), memory stick, floppy disk, mechanical coding devices, projection in a slot or a punched card stored with instructions thereon, and any appropriate combinations of the above. The computer-readable storage medium used herein is not construed as transient signals per se, such as radio waves or freely propagated electromagnetic waves, electromagnetic waves propagated via waveguide or other transmission media (such as optical pulses via fiber-optic cables), or electric signals propagated via electric wires.

The computer-readable program instruction described herein can be downloaded from the computer-readable storage medium to each computing/processing device, or to an external computer or external storage via network, such as Internet, local area network, wide area network and/or wireless network. The network can include copper-transmitted cable, optical fiber transmission, wireless transmission, router, firewall, switch, network gate computer and/or edge server. The network adapter card or network interface in each computing/processing device receives the computer-readable program instructions from the network and forwards the computer-readable program instructions for storing in the computer-readable storage medium of each computing/processing device.

The computer program instructions for executing operations of the present disclosure can be assembly instructions, instructions of instruction set architecture (ISA), machine instructions, machine-related instructions, microcodes, firmware instructions, state setting data, or source codes or target codes written in any combinations of one or more programming languages, wherein the programming languages include object-oriented programming languages, such as Smalltalk, C++ and so on, and traditional procedural programming languages, such as “C” language or similar programming languages. The computer-readable program instructions can be implemented fully on the user computer, be implemented partially on the user computer, be implemented as an independent software package, be implemented partially on the user computer and partially on the remote computer, or be implemented completely on the remote computer or server. In the case where remote computer is involved, the remote computer can be connected to the user computer via any type of network, including local area network (LAN) or wide area network (WAN), or to the external computer (e.g., connected via Internet using the Internet service provider). In some embodiments, state information of the computer-readable program instructions is used to customize an electronic circuit, e.g., programmable logic circuit, field programmable gate array (FPGA) or programmable logic array (PLA). The electronic circuit can execute computer-readable program instructions to implement various aspects of the present disclosure.

Various aspects of the present disclosure are described here with reference to the flowchart and/or block diagram of methods, devices (systems) and computer program products according to the embodiments of the present disclosure. It should be understood that each block of the flowchart and/or block diagram and the combination of various blocks in the flowchart and/or block diagram can be implemented by computer-readable program instructions.

The computer-readable program instructions can be provided to the processor in the voice interaction apparatus, the processing unit of general-purpose computer, dedicated computer or other programmable data processing apparatuses to manufacture a machine, such that the instructions, when executed by the processing unit of the computer or other programmable data processing apparatuses, generate an apparatus for implementing functions/actions stipulated in one or more blocks in the flowchart and/or block diagram. The computer-readable program instructions can also be stored in the computer-readable storage medium and cause the computer, programmable data processing apparatus and/or other devices to work in a particular manner, such that the computer-readable medium stored with instructions contains an article of manufacture, including instructions for implementing various aspects of the functions/actions stipulated in one or more blocks of the flowchart and/or block diagram.

The computer-readable program instructions can also be loaded into computer, other programmable data processing apparatuses or other devices, so as to execute a series of operation steps on the computer, other programmable data processing apparatuses or other devices to generate a computer-implemented procedure. Therefore, the instructions executed on the computer, other programmable data processing apparatuses or other devices implement the functions/actions stipulated in one or more blocks of the flowchart and/or block diagram.

The flowchart and block diagram in the drawings illustrate system architecture, functions and operations that may be implemented by the devices, methods and computer program products according to the multiple embodiments of the present disclosure. In this regard, each block in the flowchart or block diagram may represent a module, a part of program segment or code, wherein the module and the part of program segment or code comprise one or more executable instructions for performing stipulated logic functions. In some alternative implementations, the functions indicated in the block can also take place in an order different from the one indicated in the drawings. For example, two successive blocks can be in fact executed in parallel or sometimes in a reverse order depending on the involved functions. It should also be noted that each block in the block diagram and/or flowchart and combinations of the blocks in the block diagram and/or flowchart can be implemented by a hardware-based system exclusive for executing stipulated functions or actions, or by a combination of dedicated hardware and computer instructions.

In addition, it will be understood that the process described above is only exemplary. Although the steps of a method are described in the specification in a particular order, this does not require or imply that the operations must be performed in that particular order, or all illustrated operations must be performed in order to achieve a desired result. Rather, the depicted steps may be performed in a different order. Additionally or alternatively, certain steps may be omitted, multiple steps may be combined into one step for execution, and/or one step may be decomposed into multiple step for execution.

While the invention has been illustrated and described in detail in the drawings and foregoing description, such illustration and description are to be considered illustrative or exemplary and not restrictive; the present invention is not limited to the disclosed embodiments. Other variations to the disclosed embodiments can be understood and practiced by those skilled in the art in practicing the claimed invention, from a study of the drawings, the disclosure, and the appended claims.

In the claims, the word “comprising” does not exclude other elements, and the indefinite article “a” or “an” does not exclude a plurality. A single element or other unit may fulfill the functions of several items recited in the claims. The mere fact that certain features are recited in mutually different embodiments or in dependent claims does not indicate that a combination of these features cannot be used to advantage. The protection scope of the present application covers any possible combination of the features recited in the various embodiments or in the dependent claims, without departing from the spirit and scope of the present application.

Furthermore, any reference numbers in the claims shall not be construed as limiting the scope of the invention.

1. A method for optical measurement, comprising:
generating input data for inputting to a neural network model based on coordinate data of dispersion curve data and preset values of geometric parameters with respect to a reference model;
extracting features of the input data based on the neural network model trained via a plurality of samples, so as to generate simulated dispersion curve data associated with the preset values of the geometric parameters, the simulated dispersion curve data indicating a plurality of optical responses corresponding to a plurality of coordinate data of the dispersion curve data;
obtaining measured dispersion curve data in relation to a measuring object;
calculating a distance of the measured dispersion curve data from the simulated dispersion curve data, so as to determine whether the distance meets a predetermined condition;
in response to determining the distance does not meet the predetermined condition, determining a gradient for updating the preset values of the geometric parameters with respect to the reference model based on the distance, so as to regenerate simulated dispersion curve data via the neural network model based on the updated preset values to recalculate the distance; and
in response to determining the distance meets the predetermined condition, determining the geometric parameters of the measuring object based on preset values corresponding to the input data for generating the current simulated dispersion curve data.

2. The method of claim 1,
wherein the coordinate data comprises: angle and wavelength, or frequency and wave vector.

3. The method of claim 1, wherein determining the gradient for updating the preset values of the geometric parameters with respect to the reference model based on the distance, so as to regenerate the simulated dispersion curve data to recalculate the distance comprises:
determining the gradient for updating the preset values of the geometric parameters with respect to the reference model based on the distance;
updating the preset values of the geometric parameters with respect to the reference model based on the gradient, so as to generate updated input data based on the updated preset values; and
inputting the updated input data to the neural network model, and regenerating simulated dispersion curve data associated with the updated preset value.

4. The method of claim 1, wherein generating the simulated dispersion curve data associated with the preset values of the geometric parameters comprises:
based on predetermined geometric parameters with respect to the reference model and coordinate data of the dispersion curve data varying within a predetermined range, generating reflectivity data corresponding to each coordinate data varying within the predetermined range via the neural network model; and
generating the simulated dispersion curve data based on the each coordinate data varying within the predetermined range and reflectivity data corresponding to the each coordinate data.

5. The method of claim 1, wherein the simulated dispersion curve data comprises a thin film interference portion indicating a smooth change and a grating energy band portion indicating an abrupt-sharp change, the measuring object being a grating.

6. The method of claim 1, wherein a plurality of samples used to train the neural network model are generated based on a rigorous coupled wave analysis algorithm or a finite difference time domain algorithm.

7. The method of claim 4, wherein generating the reflectivity data corresponding to the each coordinate data varying within the predetermined range via the neural network model comprises:
generating a plurality of sub-input data based on the predetermined geometric parameters with respect to the reference model and the coordinate data of the dispersion curve data varying within the predetermined range;
inputting the plurality of sub-input data to a plurality of neural network models configured on a plurality of GPUs, respectively, the plurality of sub-input data comprising same predetermined geometric parameters and different coordinate data; and
extracting features of the corresponding sub-input data respectively via the plurality of neural network models, so as to respectively generate a plurality of reflectivity data corresponding to coordinate data comprised in the plurality of sub-input data.

8. The method of claim 1, wherein generating the simulated dispersion curve data associated with the preset values of the geometric parameters comprises:
randomly determining a plurality of initialized preset values of the geometric parameters with respect to the reference model;
generating a plurality of candidate simulated dispersion curve data associated with the plurality of initialized preset values respectively via the neural network model based on the plurality of initialized preset values;
comparing a plurality of first distances between the plurality of candidate simulated dispersion curve data and the measured dispersion curve data, so as to respectively update gradients of the plurality of initialized preset values based on the plurality of first distances, for determining candidate simulated dispersion curve data enabling the corresponding first distances reach a minimum value;
comparing a plurality of second distances between the candidate simulated dispersion curve data enabling the corresponding first distances reach the minimum value and the measured dispersion curve data, respectively, so as to take the candidate simulated dispersion curve data corresponding to the minimum second distance as target dispersion curve data; and
computing the geometric parameters of the measuring object based on the target simulated dispersion curve data.

9. The method of claim 1, wherein the predetermined condition comprises one of the followings:
the Euclidean distance between the measured dispersion curve data and the simulated dispersion curve data is the smallest; and
the Euclidean distance between the measured dispersion curve data and the simulated dispersion curve data is less than a predetermined threshold.

10. The method according to claim 1, wherein the measured dispersion curve data is a dispersion curve graph of the measuring object in momentum space under irradiation of incident light obtained based on measured dispersion curve data of momentum space of the background in which the measuring object is located, dispersion curve data of momentum space of a light source, and measured initial dispersion curve data of momentum space of the measuring object.

11. A computing device, comprising:
a memory configured to store one or more computer programs; and
a processor coupled to the memory and configured to execute the one or more programs to cause a measuring apparatus to:
generate input data for inputting to a neural network model based on coordinate data of dispersion curve data and preset values of geometric parameters with respect to a reference model;
extract features of the input data based on the neural network model trained via a plurality of samples, so as to generate simulated dispersion curve data associated with the preset values of the geometric parameters, the simulated dispersion curve data indicating a plurality of optical responses corresponding to a plurality of coordinate data of the dispersion curve data;
obtain measured dispersion curve data in relation to a measuring object;
calculate a distance of the measured dispersion curve data from the simulated dispersion curve data, so as to determine whether the distance meets a predetermined condition; and
in response to determining the distance does not meet the predetermined condition, determine a gradient for updating the preset values of the geometric parameters with respect to the reference model based on the distance, so as to regenerate simulated dispersion curve data via the neural network model based on the updated preset values to recalculate the distance.

12. (canceled)

13. A measuring system, comprising:
an angle-resolved spectrometry configured to measure an object based on incident light so as to generate an optical energy band with respect to the measuring object; and
a computing device configured to be operable to:
generate input data for inputting to a neural network model based on coordinate data of dispersion curve data and preset values of geometric parameters with respect to a reference model;
extract features of the input data based on the neural network model trained via a plurality of samples, so as to generate simulated dispersion curve data associated with the preset values of the geometric parameters, the simulated dispersion curve data indicating a plurality of optical responses corresponding to a plurality of coordinate data of the dispersion curve data;
obtain measured dispersion curve data in relation to a measuring object;
calculate a distance of the measured dispersion curve data from the simulated dispersion curve data, so as to determine whether the distance meets a predetermined condition; and
in response to determining the distance does not meet the predetermined condition, determine a gradient for updating the preset values of the geometric parameters with respect to the reference model based on the distance, so as to regenerate simulated dispersion curve data via the neural network model based on the updated preset values to recalculate the distance.
